(19) United States
(12) Patent Application Publication
(10) Pub. No.: US 2009/0283299 A1
(43) Pub. Date: Nov. 19, 2009

(54) COMPONENT-EMBEDDED PRINTED CIRCUIT BOARD, METHOD OF MANUFACTURING THE SAME, AND ELECTRONIC APPARATUS INCLUDING THE SAME

(75) Inventor: Daigo SUZUKI, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/427,605

(22) Filed: Apr. 21, 2009

(30) Foreign Application Priority Data
May 13, 2008 (JP) 2008-126082

(51) Int. Cl. H05K 1/09; H05K 3/10

(52) U.S. Cl. 174/251; 29/829

(57) ABSTRACT

According to one embodiment, a component-embedded printed circuit board is provided with a built-in component mounted on a component mounting surface of a substrate and enclosed by an insulating layer, an interior pattern layer for heat radiation which is provided on the opposite side of the built-in component from the substrate and radiates heat generated from the built-in component, and an exterior pattern layer for heat radiation connected to the interior pattern layer for heat radiation.

### CROSS-REFERENCE TO RELATED APPLICATIONS

This application is based upon and claims the benefit of priority from Japanese Patent Application No. 2008-126082, filed May 13, 2008, the entire contents of which are incorporated herein by reference.

### BACKGROUND

1. Field

One embodiment of the present invention relates to a component-embedded printed circuit board with built-in electronic components, a method of manufacturing the same, and an electronic apparatus including the same.

2. Description of the Related Art

Small electronic apparatuses, such as portable computers, mobile terminals, etc., require a technique for component mounting on boards that enable high-density wiring with high circuit design flexibility to meet the requirements for thinner, shorter configurations. There is a laminated printed circuit board that is embedded with some circuit components in its inner layer in order to ensure high-density wiring. This component-embedded printed circuit board, having the circuit components embedded in its inner layer, needs a heat radiation measure to counter heat generation by the built-in components.

A heat radiation technique for built-in components in one such component-embedded printed circuit board is described in, for example, Jpn. Pat. Appln. KOKAI Publication No. 2003-60354. According to this technique, heat generated in the built-in components is guided to the outer layer side through via-holes that connect layers.

Since this heat radiation technique is designed so that the heat is guided to the outer layer side through the via-holes, its heat radiation efficiency is not very high. Thus, a satisfactory heat radiation effect cannot be expected if an electronic component with a high heat release rate or a plurality of electronic components that generate heat are embedded in the board.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary sectional view showing a configuration of a component-embedded printed circuit board according to a first embodiment of the invention;

FIG. 2 is an exemplary sectional view showing a configuration of a component-embedded printed circuit board according to a second embodiment of the invention;

FIG. 3 is an exemplary sectional view showing a configuration of a component-embedded printed circuit board according to a third embodiment of the invention;

FIG. 4 is an exemplary sectional view showing a configuration of a component-embedded printed circuit board according to a fourth embodiment of the invention;

FIG. 5 is an exemplary sectional view showing a configuration of a component-embedded printed circuit board according to a fifth embodiment of the invention;

FIG. 6 is an exemplary sectional view showing a manufacturing process for the component-embedded printed circuit board according to the second embodiment of the invention;

FIG. 7 is an exemplary sectional view showing a manufacturing process for the same component-embedded printed circuit board;

FIG. 8 is an exemplary sectional view showing a manufacturing process for the same component-embedded printed circuit board;

FIG. 9 is an exemplary sectional view showing a manufacturing process for the same component-embedded printed circuit board;

FIG. 10 is an exemplary sectional view showing a manufacturing process for the same component-embedded printed circuit board;

FIG. 11 is an exemplary sectional view showing a manufacturing process for the same component-embedded printed circuit board;

FIG. 12 is an exemplary sectional view showing a manufacturing process for the same component-embedded printed circuit board;

FIG. 13 is an exemplary sectional view showing a manufacturing process for the same component-embedded printed circuit board;

FIG. 14 is an exemplary view showing another configuration example of an exterior pattern layer for heat radiation according to each of the embodiments of the invention;

FIG. 15 is an exemplary perspective view showing a configuration of an electronic apparatus according to a sixth embodiment of the invention;

FIG. 16 is an exemplary perspective view showing an internal configuration of the electronic apparatus according to the sixth embodiment; and

FIG. 17 is an exemplary view showing a configuration of a principal part of the electronic apparatus according to the sixth embodiment.

### DETAILED DESCRIPTION

Various embodiments according to the invention will be described hereinafter with reference to the accompanying drawings. In general, according to one embodiment of the invention, there is provided a component-embedded printed circuit board comprising: a first substrate having a component mounting surface on an inner layer side thereof, a second substrate laminated to the first substrate with an insulating layer therebetween, a built-in component mounted on the component mounting surface and covered by the insulating layer, an interior pattern layer for heat radiation which is provided on an inner layer side of the second substrate and radiates heat generated from the built-in component, and an exterior pattern layer for heat radiation connected to the interior pattern layer.

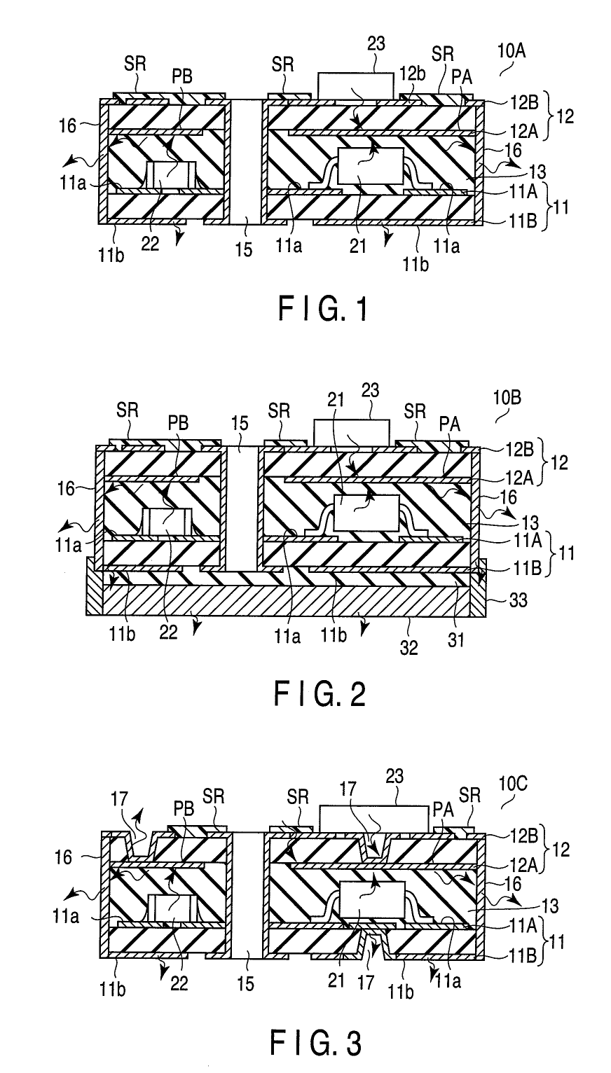

As shown in FIG. 1, for example, a component-embedded printed circuit board according to each embodiment of the invention includes a built-in component 21, an interior pattern layer PA for heat radiation, and an exterior pattern layer 16 for heat radiation. The built-in component 21 is mounted on a component mounting surface of a substrate 11 and enclosed by an insulating layer 13. The interior pattern layer PA is provided on the opposite side of the built-in component 21 from the component mounting surface of the substrate 11 and radiates heat generated from the component 21. The exterior pattern layer 16 is connected to the interior pattern layer PA. Thus, the interior pattern layer PA and the exterior pattern layer 16 that is conductively connected (or conductor-connected) to the layer PA form a heat radiation path for the built-in component 21. In consequence, the heat generated in the component 21 can be efficiently radiated to the outside without depending only on via-holes for heat radiation.

The component-embedded printed circuit boards according to the following embodiments are applicable to various multilayer printed circuit boards including an arbitrary number of layers. For ease of illustration, however, a multilayer printed circuit board is given as an example in which two substrates, having electrically-conductive layers formed on their opposite sides, individually, are laminated to each other with an insulating layer between them, thereby realizing a four-layer wiring. In a laminated structure based on first and second substrates, according to each of the embodiments, conductor layers that are formed on the lamination side of one another are referred to as inside conductor layers, and an exposed conductor layer (outermost layer) on the surface layer side as an outside conductor layer.

FIG. 1 shows a configuration of a principal part of a printed circuit board according to a first embodiment of the invention. As shown in FIG. 1, a component-embedded printed circuit board 10A according to the first embodiment includes a first substrate 11, a second substrate 12, an inside conductor layer 11A, built-in components 21 and 22, interior pattern layers PA and PB for heat radiation, and an exterior pattern layer 16 for heat radiation. The second substrate 12 is laminated to the first substrate 11 with an insulating layer 13 between them. The inside conductor layer 11A is provided on the inner layer side of the first substrate 11 and forms a component mounting surface. The built-in components 21 and 22 are mounted on the component mounting surface 11A and covered by the insulating layer 13. The interior pattern layers PA and PB are provided on an inside conductor layer 12A of the second substrate 12 and radiates heat generated from the built-in components 21 and 22. The exterior pattern layer 16 is conductor-connected to the interior pattern layers PA and PB for heat radiation.

The first substrate 11 includes the inside conductor layer 11A and an outside conductor layer 11B. Component mounting pads 11a on which the built-in components 21 and 22 are mounted individually are formed on the inside conductor layer 11A that forms the component mounting surface. The outside conductor layer 11B forms a wiring layer (copper foil pattern layer). An outer-surface solid pattern layer 11b is formed on the outside conductor layer 11B. The solid pattern layer 11b is conductively connected to the exterior pattern layer 16 for heat radiation, which will be described later.

The second substrate 12 includes the inside conductor layer 12A and an outside conductor layer 12B. The inside conductor layer 12A forms a wiring layer (copper foil pattern layer). The conductor layer 12A is provided with the interior pattern layers PA and PB for heat radiation having predetermined shapes and regions such as to cover the built-in components 21 and 22 mounted on the first substrate 11. In this embodiment, solid pattern layers that cover entire component mounting regions of the built-in components 21 and 22 with the insulating layer 13 therebetween are provided as the interior pattern layers PA and PB, individually. The interior pattern layers PA and PB are conductor-connected to the exterior pattern layer 16 for heat radiation (mentioned later). The outside conductor layer 12B forms a component mounting surface. A component mounting pad 12b on which a surface-mounted component 23 is mounted is formed on the outside conductor layer 12B.

The built-in components 21 and 22 that generate heat during operation are mounted individually on the component mounting pads 11a that are provided on the inside conductor layer 11A of the first substrate 11. The built-in components 21 and 22 are mounted on the inside conductor layer 11A so as to be enclosed by the insulating layer 13. The surface-mounted component 23 is mounted on the component mounting pad 12b that is provided on the outside conductor layer 12B of the second substrate 12. A solder resist film SR is coated on a required part of the outside conductor layer 12B of the second substrate 12 on which the surface-mounted component 23 is mounted.

A through-hole 15 that penetrates the first and second substrates 11 and 12 is provided near positions where the built-in components 21 and 22 are mounted. The through-hole 15 doubles as a heat radiation path for circuit wiring and the components 21 and 22.

The exterior pattern layer 16 for heat radiation is formed on side surfaces of the body of the printed circuit board that includes the first and second substrate 11 and 12 laminated to each other so as to cover the entire peripheral surface. The exterior pattern layer 16 is conductively connected to the interior pattern layers PA and PB for heat radiation formed on the inside conductor layer 12A of the second substrate 12 and the outer-surface solid pattern layer 11b formed on the outside conductor layer 11B of the first substrate 11. The exterior pattern layer 16, along with the outer-surface solid pattern layer 11b, forms an exposed pattern layer for heat radiation.

The heat that is generated in the built-in components 21 and 22 as the interior and exterior pattern layers are connected is transmitted to the exterior pattern layer 16 for heat radiation via the interior pattern layers PA and PB for heat radiation, as indicated by arrows in FIG. 1. The transmitted heat is diffused into the atmosphere from the exterior pattern layer 16 and the outer-surface solid pattern layer 11b with substantially the entire circumference of the component-embedded printed circuit board 10A used as a heat radiation pattern. Thus, the heat generated in the built-in components 21 and 22 can be radiated efficiently and quickly without depending only on the via-holes for heat radiation. For the surface-mounted component 23, moreover, a heat radiation path is formed extending through the interior pattern layer PA and the exterior pattern layer 16, as indicated by arrows in FIG. 1, in addition to the radiation path extending through the. through-hole 15. Heat generated in the surface-mounted component 23 can be radiated efficiently and quickly through this additional heat radiation path.

FIG. 2 shows a configuration of a principal part of a component-embedded printed circuit board according to a second embodiment of the invention. According to this second embodiment shown in FIG. 2, which is based on the component-embedded printed circuit board of the first embodiment, the heat radiation efficiency is improved to enable mounting of a built-in component with a high heat radiation rate. Like reference numbers are used to designate like portions or component elements of the printed circuit boards of the first and second embodiments shown in FIGS. 1 and 2, respectively.

In a component-embedded printed circuit board 10B according to the second embodiment shown in FIG. 2, an outside conductor layer 11B of a first substrate 11 is provided with a metal plate 32 for heat radiation with an insulating layer 31 of glass epoxy resin between them.

The metal plate 32 for heat radiation is laminated to the outside conductor layer 11B of the first substrate 11 with the glass epoxy resin (or the insulating layer 31) therebetween by, for example, press working and integrated with the body of the printed circuit board. The insulating layer 31 is formed with a thickness of, for example, about 60 μm and forms a heat conduction path between the outer-surface solid pattern layer 11b and the metal plate 32. Further, an exterior junction 33 formed of an electrically-conductive adhesive is provided on side surfaces of the metal plate 32. The exterior junction 33 forms a heat conduction path between the metal plate 32 and the exterior pattern layer 16 for heat radiation. According to this arrangement, a heat conduction path that extends through the exterior junction 33 is formed between the exterior pattern layer 16 and the metal plate 32 in addition to the one that extends through the insulating layer 31.

Furthermore, the metal plate 32 for heat radiation doubles as a mounting seat for mounting the component-embedded printed circuit board 10B on a matrix, such as a motherboard, housing, etc. An exposed surface of the metal plate 32 is conductively connected to the matrix using a solder or adhesive. By doing this, heat generated in the built-in components 21 and 22 can be radiated from the exterior pattern layer 16 for heat radiation into the atmosphere through the interior pattern layers PA and PB for heat radiation and radiated to the matrix through the metal plate 32. Thus, the heat generated in the built-in components can be radiated more efficiently and quickly than in the case of the first embodiment.

FIG. 3 shows a configuration of a principal part of a component-embedded printed circuit board according to a third embodiment of the invention. According to this third embodiment shown in FIG. 3, which is based on the component-embedded printed circuit board of the first embodiment, the heat radiation efficiency is improved to enable mounting of a built-in component with a high heat radiation rate. Like reference numbers are used to designate like portions or component elements of the printed circuit boards of the first and third embodiments shown in FIGS. 1 and 3, respectively.

In a component-embedded printed circuit board 10C according to the third embodiment shown in FIG. 3, heat radiation paths based on interstitial via-holes (IVHs) are provided in addition to the exterior pattern layer 16 for heat radiation. Since the printed circuit board 10C has a four-layer structure, according to this third embodiment, blind via-holes (BVHs) 17 are provided as IVHs for heat radiation, which serve to improve the heat radiation efficiency. In the third embodiment shown in FIG. 3, the BVH 17 in a first substrate 11 forms a heat radiation path for a built-in component 21, and the BVHs 17 in a second substrate 12 form heat radiation paths from interior pattern layers PA and PB for heat radiation to an outside conductor layer 12B and a heat radiation path for a surface-mounted component 23. Thus, the BVHs 17 promote heat radiation by the exterior pattern layer 16. The BVHs 17 may be via-holes that are formed by either laser beam processing or drilling.

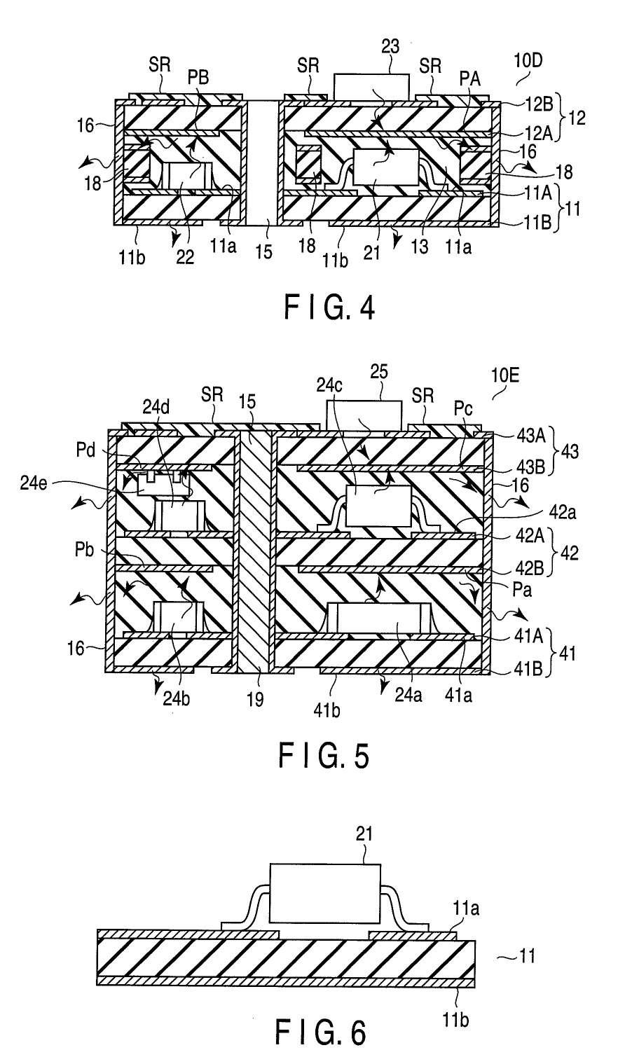

FIG. 4 shows a configuration of a principal part of a component-embedded printed circuit board according to a fourth embodiment of the invention. According to this fourth embodiment shown in FIG. 4, which is based on the component-embedded printed circuit board of the first embodiment, the heat radiation efficiency is improved to enable mounting of a built-in component with a high heat radiation rate. Like reference numbers are used to designate like portions or component elements of the printed circuit boards of the first and fourth embodiments shown in FIGS. 1 and 4, respectively.

In a component-embedded printed circuit board 10D according to the fourth embodiment shown in FIG. 4, an insulating layer 13 to which a first substrate 11 and a second substrate 12 are laminated is provided with hollow core members 18 with solid pattern layers. The core members 18 are incorporated as heat conduction members in the insulating layer 13. The core members (heat conduction members) 18 serve to improve heat conduction through heat radiation paths from built-in components 21 and 22 to interior pattern layers PA and PB and heat radiation paths from the interior pattern layers PA and PB to an exterior pattern layer 16 for heat radiation.

FIG. 5 shows a configuration of a principal part of a component-embedded printed circuit board according to a fifth embodiment of the invention. In a configuration example according to this fifth embodiment shown in FIG. 5, a high-density component-embedded printed circuit board is realized as a more multilayered structure, based on the component-embedded printed circuit board according to the first embodiment. Like reference numbers are used to designate like portions or component elements of the printed circuit boards of the first and fifth embodiments shown in FIGS. 1 and 5, respectively.

A component-embedded printed circuit board 10E according to the fifth embodiment shown in FIG. 5 has a six-layer structure such that an additional component mounting substrate is laminated to the outer layer side of the first substrate 11 in the component-embedded printed circuit board 10A of the first embodiment shown in FIG. 1. The printed circuit board 10E of the fifth embodiment shown in FIG. 5 is provided with a first substrate 41, a second substrate 42 laminated to the first substrate 41 with an insulating layer between them, and a third substrate 43 laminated to the second substrate 42 with an insulating layer between them. Built-in components 24a and 24b are mounted on an inside conductor layer 41A of the first substrate 41, and an outer-surface solid pattern layer 41b is formed on an outside conductor layer 41B. Built-in components 24c and 24d are mounted on a conductor layer 42A of the second substrate 42 on the side opposite the third substrate 43, and interior pattern layers Pa and Pb for heat radiation of the built-in components 24a and 24b are formed on a conductor layer 42B on the side opposite the first substrate 41. A surface-mounted component 25 is mounted on an outside conductor layer 43A of the third substrate 43, and interior pattern layers Pc and Pd for heat radiation of the built-in components 24c and 24d are formed on an inside conductor layer 43B. Further, a built-in component 24e is mounted on the inside conductor layer 43B. A solder resist film SR is coated on a required part of the outside conductor layer 43A of the third substrate 43 on which the surface-mounted component 25 is mounted. A through-hole 15 that penetrates the first, second, and third substrates 41, 42 and 43 is provided near positions where the built-in components 24a, 24b, 24c, 24d and 24e are mounted. The through-hole 15 doubles as a heat radiation path for circuit wiring and the components 24a, 24b, 24c, 24d and 24e.

An exterior pattern layer 16 for heat radiation is formed on side surfaces of the body of the printed circuit board to which the first, second, and third substrate 41, 42 and 43 are laminated so as to cover the entire peripheral surface. The exterior pattern layer 16 is conductively connected to the outer-surface solid pattern layer 41b on the outside conductor layer 41B of the first substrate 41, the interior pattern layers Pa and Pb for heat radiation of the built-in components 24a and 24b on a conductor layer 42B of the second substrate 42, and the interior pattern layers Pc and Pd for heat radiation of the built-in components 24c and 24d on the inside conductor layer 43B of the third substrate 43. The exterior pattern layer 16, along with the outer-surface solid pattern layer 41b, forms an exposed pattern layer for heat radiation.

Heat that is generated in the built-in components 24a, 24b, 24c, 24d and 24e as the interior and exterior pattern layers are connected is transmitted to the exterior pattern layer 16 for heat radiation via the interior pattern layers Pa, Pb, Pc and Pd for heat radiation. The transmitted heat is diffused into the atmosphere from the exterior pattern layer 16 and the outer-surface solid pattern layer 41b with substantially the entire circumference of the component-embedded printed circuit board 10E used as a heat radiation pattern. Thus, the heat generated in the built-in components can be radiated efficiently and quickly.

In a configuration where electronic components that generate heat during operation are laminated to a plurality of inner layers, as in the component-embedded printed circuit board 10E of the fifth embodiment, a component mounting pad on which a built-in electronic component with a higher heat radiation efficiency are to be mounted is located near the exterior pattern layer 16 for heat radiation. By doing this, heat can be radiated more efficiently from the built-in electronic components. In the component-embedded printed circuit board 10E of the fifth embodiment shown in FIG. 5, component mounting pads 41a and 42a for the built-in components 24a and 24c with a higher heat release rate, among the built-in components 24a, 24b, 24c, 24d and 24e, are located near the exterior pattern layer 16 for heat radiation. By doing this, heat generated from the built-in components 24a and 24c mounted on the component mounting pads 41a and 42a can be transmitted to the exterior pattern layer 16 through a short circuit and radiated efficiently and quickly.

The second to fifth embodiments described above are not limited to the illustrated configurations, and novel component-embedded printed circuit boards can be realized by suitably combining the component elements shown in FIGS. 2 to 5.

Processes of manufacturing the component-embedded printed circuit board according to each of the foregoing embodiments (represented by the component-embedded printed circuit board 10B of the second embodiment shown in FIG. 2) will now be described with reference to FIGS. 6 to 13.

In process 1 shown in FIG. 6, the electronic component 21 as a built-in component is mounted on the component mounting pad 11a of the first substrate 11. The outer-surface solid pattern layer 11b is formed on the outside conductor layer of the first substrate 11.

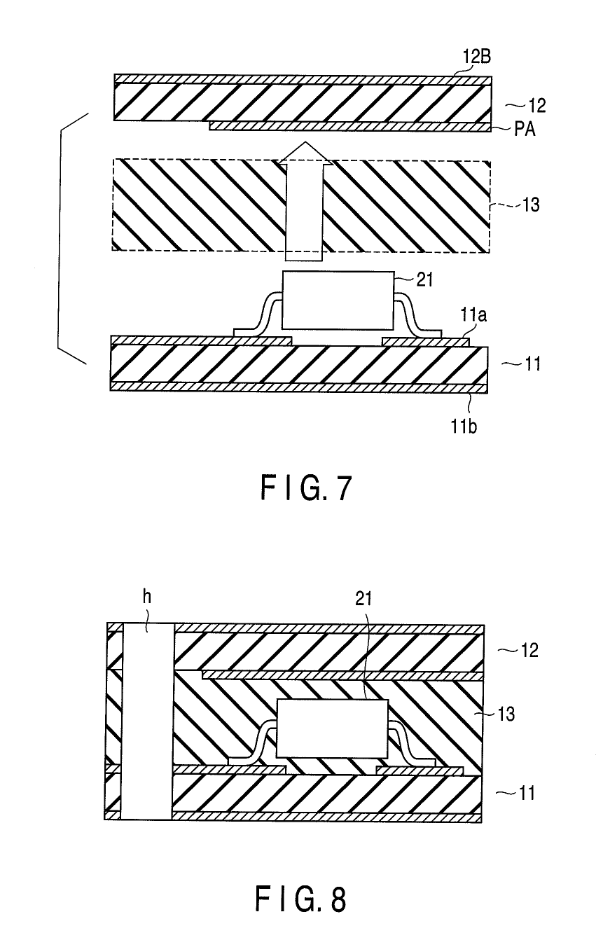

In process 2 shown in FIG. 7, the second substrate 12 is laminated to the first substrate 11 with the insulating layer 13 between them by press-working.

In process 3 shown in FIG. 8, the printed circuit board body that includes the first and second substrates 11 and 12 laminated to each other is subjected to boring such as to form a through-hole, via-hole, etc., by, for example, laser beam processing or drilling. In this example, a hole h is bored to form the through-hole 15.

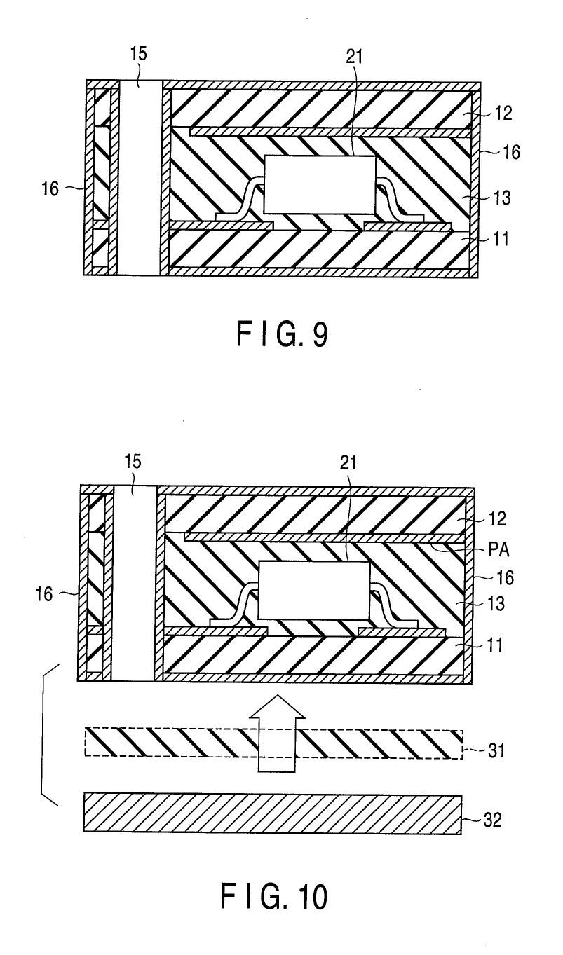

Hole plating is performed in process 4 shown in FIG. 9. In this plating process, the exterior pattern layer 16 for heat radiation is formed on the side surfaces of the printed circuit board body. In this example, the entire peripheral surface of the printed circuit board body is plated with a metal (e.g., copper). In this plating process for the exterior pattern layer 16, an underlayer is formed by electroless plating, and a surface layer by electroplating.

In process 5 shown in FIG. 10, the metal plate 32 for heat radiation is affixed by pressing to the printed circuit board body that is coated with the exterior pattern layer 16 for heat radiation on its entire peripheral surface, with the insulating layer 31 of the glass epoxy resin therebetween. Thus, the metal plate 32 is laminated integrally to the printed circuit board body. For example, the insulating layer (glass epoxy resin) 31 is about 60 μm thick, and the metal plate 32 is about 1 mm thick.

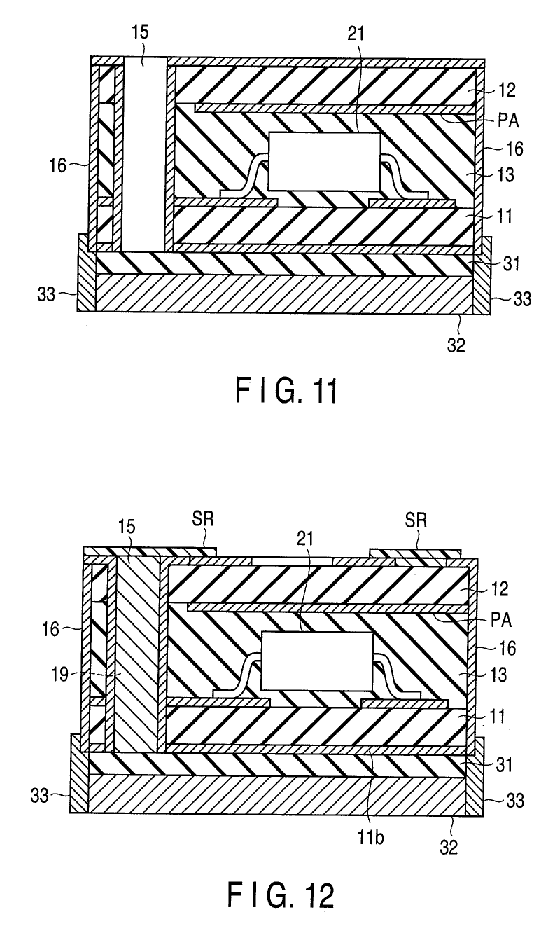

In process 6 shown in FIG. 11, the exterior junction 33 of the electrically-conductive adhesive is provided integrally on the side surfaces of the metal plate 32 for heat radiation. The exterior junction 33 forms the heat conduction path between the metal plate 32 and the exterior pattern layer 16 for heat radiation. According to this arrangement, the heat conduction path that extends through the exterior junction 33 is formed between the exterior pattern layer 16 and the metal plate 32 in addition to the one that extends through the insulating layer 31.

In process 7 shown in FIG. 12, the solder resist film SR is coated on the whole required part of the outside conductor layer 12B of the second substrate 12 except a terminal junction for the mounted component. In this coating process for the solder resist film SR, an electrically-conductive paste 19 as a heat conduction member (not shown in FIG. 2 that illustrates the structure of the component-embedded printed circuit board 10B) is embedded in the through-hole 15, which is closed by the solder resist film SR.

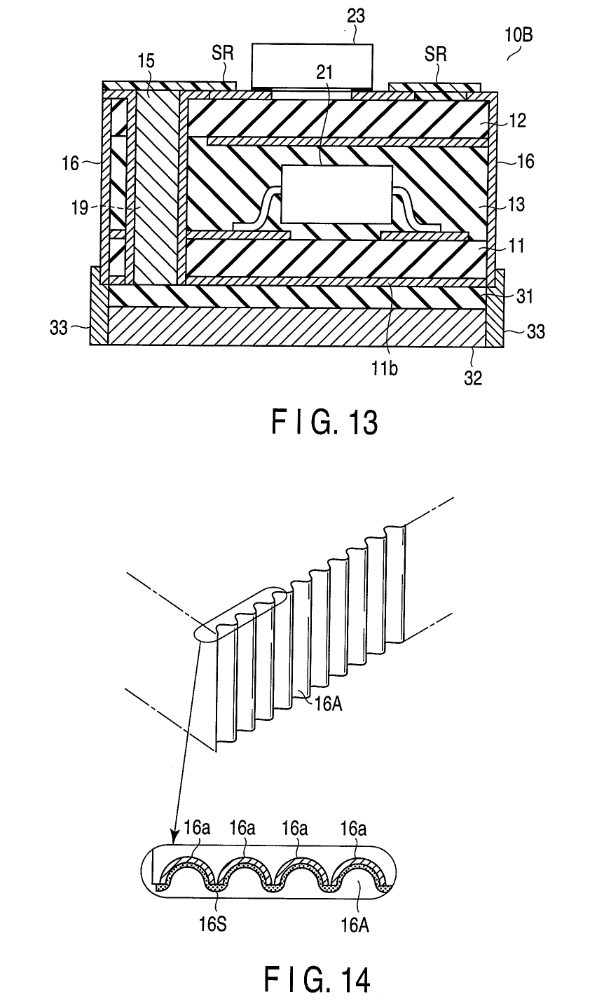

In process 8 shown in FIG. 13, the surface-mounted component 23 is mounted on the outside conductor layer 12B of the second substrate 12. When these processes are accomplished, the component-embedded printed circuit board 10B is manufactured having the heat radiation path for the built-in component 21, the heat radiation path directly conductor-connecting the interior and exterior pattern layers PA and 16 for heat radiation and the metal plate 32 for heat radiation. Further, the printed circuit board 10B is formed with the heat radiation path that is defined by the through-hole 15 with the electrically-conductive paste 19 embedded therein and the outer-surface solid pattern layer 11b and extends through the insulating layer, in addition to the aforesaid heat radiation path that extends from the interior pattern layer PA to the exterior pattern layer 16 and the metal plate 32.

The heat generated in the built-in component 21 can be radiated efficiently and quickly through the heat radiation path that directly conductor-connects the interior and exterior pattern layers PA and 16 for heat radiation and the metal plate 32 for heat radiation.

In each of the foregoing embodiments of the present invention, the exterior pattern layer 16 for heat radiation is formed by plating the side surfaces of the printed circuit board with a metal. FIG. 14 shows another configuration example of the exterior pattern layer for heat radiation. An exterior pattern layer 16A for heat radiation shown in FIG. 14 is constructed based on semicircular through-holes that are formed by cutting plated through-holes along their length.

As shown in FIG. 14, the exterior pattern layer 16A for heat radiation has a plurality of semicircular through-holes 16a and solder coats 16s. The through-holes 16a are arranged with a predetermined pitch on the side surfaces of the printed circuit board. The solder coats 16s conductor-connect the through-holes 16a as deposition parts to one another. For example, the underlayer of each semicircular through-hole 16a is formed by electroless plating, and the surface layer by electroplating. The through-holes 16a are arranged, for example, covering the entire side surfaces of the printed circuit board body along the external shape thereof.

Since the exterior pattern layer 16A for heat radiation based on the semicircular through-holes 16a has a fin structure with a corrugated surface, its heat radiation area is large, and the heat radiation efficiency can be further enhanced. In this example, the through-holes 16a are conductor-connected to one another by the solder coats 16s. Alternatively, however, the through-holes 16a may be conductor-connected by another plating process (e.g., copper plating) or by deposition of an electrically-conductive adhesive or resin.

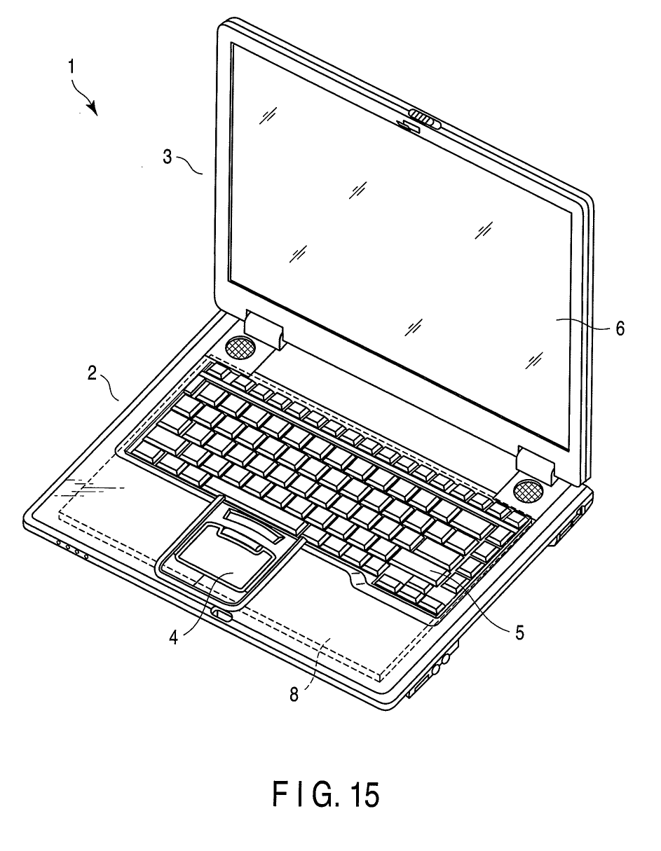

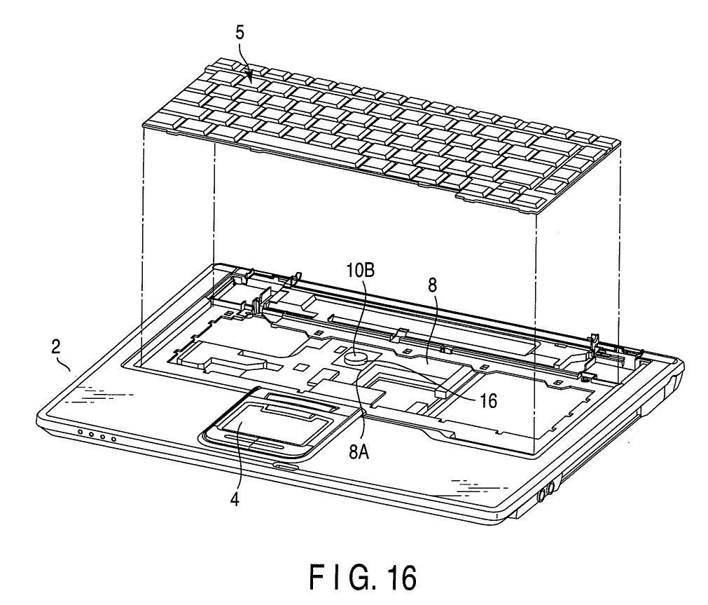

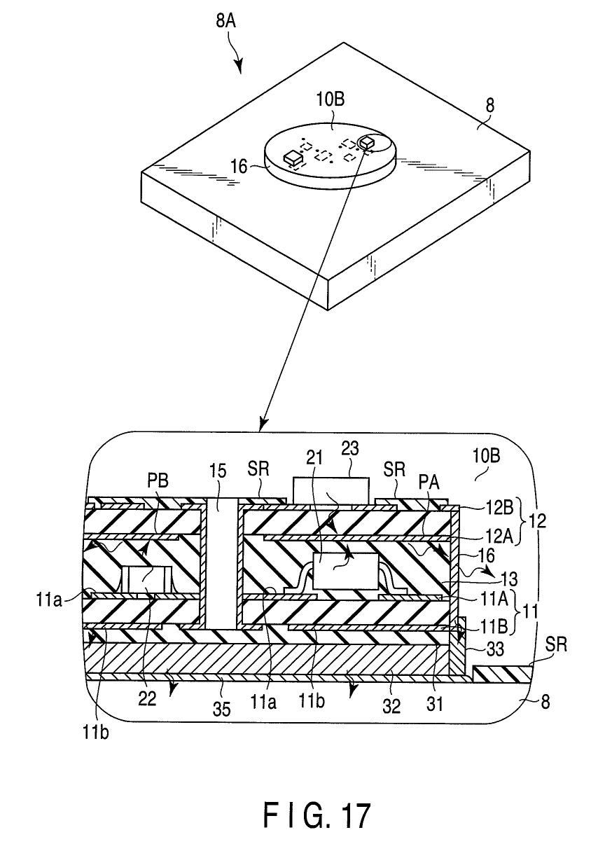

A sixth embodiment of the present invention will now be described with reference to FIGS. 15 to 17. In this sixth embodiment, an electronic apparatus includes the component-embedded printed circuit board according to any of the foregoing embodiments. In this case, a portable computer is given as an example of the electronic apparatus. FIG. 15 shows an external configuration of the portable computer according to the sixth embodiment, and FIG. 16 shows an internal configuration of the portable computer with some of its component elements (e.g., keyboard) off. FIG. 17 shows a configuration of a principal part (daughterboard mounting area 8A) shown in FIG. 16.

A display housing 3 is swingably mounted on a main body 2 of a portable computer 1 by a hinge mechanism. The main body 2 is provided with operating sections, such as a pointing device 4, a keyboard 5, etc. The display housing 3 is provided with a display device 6, such as an LCD.

Further, the main body 2 is provided with the operating sections, including the pointing device 4, keyboard 5, etc., and a circuit board (motherboard) 8 incorporated with a control circuit for controlling the display device 6. The motherboard 8 is mounted, as a daughterboard (component-embedded board), with one of the component-embedded printed circuit boards according to the first to fifth embodiments. This daughterboard includes a substrate, built-in component, interior pattern layer for heat radiation, and exterior pattern layer for heat radiation. The substrate has a component mounting surface. The built-in component is mounted on the component mounting surface and enclosed by an insulating layer. The interior pattern layer is located on the opposite side of the built-in component from the substrate and radiates heat generated from the component. The exterior pattern layer is connected to the interior pattern layer.

In the sixth embodiment, as shown in FIG. 16, the printed circuit board 10B shown in FIG. 2 is mounted as a daughterboard on the motherboard 8.

As shown in FIG. 17, the component-embedded printed circuit board 10B mounted on the motherboard 8 has a columnar external shape and is formed with a heat radiation path that directly conductor-connects interior pattern layers PA and PB for heat radiation, an exterior pattern layer 16 for heat radiation, and a metal plate 32 for heat radiation. Like reference numbers are used to designate like portions or component elements of the printed circuit boards shown in FIGS. 2 and 17.

The component-embedded printed circuit board 10B is mounted on the daughterboard mounting area 8A of the motherboard 8 in such a manner that an exposed surface of the metal plate 32 is, for example, soldered to a solid pattern layer (or mesh pattern layer) 35 that is provided on the mounting area 8A.

The component-embedded printed circuit board 10B mounted as a daughterboard on the motherboard 8 includes first and second substrates 11 and 12, built-in components 21 and 22, interior pattern layers PA and PB for heat radiation, and an exterior pattern layer 16 for heat radiation. The first and second substrates 11 and 12 are laminated to each other with an insulating layer 13 between them. The built-in components 21 and 22 are mounted on a component mounting surface 11A of the first substrate 11 and covered by the insulating layer 13. The interior pattern layers PA and PB are provided on an inside conductor layer 12A of the second substrate 12 and radiates heat generated from the components 21 and 22. The exterior pattern layer 16 is conductor-connected to the interior pattern layers PA and PB for heat radiation. The exterior pattern layer 16 for heat radiation is formed on the body of the printed circuit board that includes the first and second substrate 11 and 12 laminated to each other so as to cover the entire peripheral surface thereof. The exterior pattern layer 16 is conductor-connected to the interior pattern layers PA and PB for heat radiation formed on the inside conductor layer 12A of the second substrate 12 and an outer-surface solid pattern layer 11b formed on the outside conductor layer 11B of the first substrate 11.

With the heat radiation structure of the daughterboard described above, the heat generated from the built-in components 21 and 22 is transmitted to the exterior pattern layer 16 for heat radiation via the interior pattern layers PA and PB for heat radiation, and further transmitted from the exterior pattern layer 16 to the motherboard 8 through an exterior junction 33, the metal plate 32 for heat radiation, and the solid pattern layer (or mesh pattern layer) 35. All heat radiation paths (see arrows in FIG. 17) from the interior pattern layers PA and PB for heat radiation to the daughterboard mounting area 8A of the motherboard 8 are conductor-connected to one another, and the exterior pattern layer 16 is exposed to the open air. Therefore, the heat generated in the built-in components 21 and 22 can be radiated from the exterior pattern layer 16 into the atmosphere through the interior pattern layers PA and PB and also radiated to the matrix (motherboard 8) through the metal plate 32. Thus, the heat generated in the built-in components in the daughterboard can be radiated efficiently and quickly through the metal plate 32. For a surface-mounted component 23, moreover, a similar heat radiation path (see arrows in FIG. 17) is formed extending through the interior pattern layer PA and the exterior pattern layer 16, in addition to the radiation path extending through a through-hole 15. Heat generated in the surface-mounted component 23 can be radiated efficiently and quickly through this additional heat radiation path.

According to the embodiments of the present invention, as described in detail herein, the heat generated in the built-in components can be radiated efficiently.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A component-embedded printed circuit board comprising:
a first substrate comprising a component mounting surface on an inner layer side of the first substrate;
a second substrate layered to the first substrate with an insulating layer between the first and second substrates;
a built-in component on the component mounting surface and under the insulating layer;
an interior pattern layer on an inner layer side of the second substrate configured to radiate heat from the built-in component; and
an exterior pattern layer connected to the interior pattern layer.

2. The component-embedded printed circuit board of claim 1, wherein the exterior pattern is on side surfaces of a body of the printed circuit board comprising the first and second substrates.

3. The component-embedded printed circuit board of claim 2, wherein an outer-surface solid pattern layer connected to the exterior pattern is on an outer layer side of the first substrate.

4. The component-embedded printed circuit board of claim 3, wherein a metal plate for heat radiation is on the outer layer side of the first substrate with an insulating layer between the metal plate and the first substrate.

5. The component-embedded printed circuit board of claim 4, wherein an exterior junction comprising an electrically-conductive adhesive is on side surfaces of the metal plate, the electrically-conductive adhesive being a heat conduction path between the metal plate and the exterior pattern layer.

6. The component-embedded printed circuit board of claim 2, wherein the second substrate comprises a component mounting surface on an outer layer side of the second substrate.

7. The component-embedded printed circuit board of claim 2, wherein a through-hole is configured to connect through the first and second substrates.

8. The component-embedded printed circuit board of claim 2, wherein an outer surface of the body of the printed circuit board is with a semicircular through-hole being a plated through-hole cut along the length, the exterior pattern layer being on the outer surface based on the semicircular through-hole.

9. A method of manufacturing a component-embedded printed circuit board, comprising:
laminating a first substrate with an electronic component on a component mounting surface of the first substrate and a second substrate comprising a pattern formation surface comprising an interior pattern layer configured to radiate heat from the electronic component to each other with an insulating layer between the first and second substrates in a state where the component mounting surface and the pattern formation surface are configured to face to each other, the electronic component placed under the insulating layer; and
forming an exterior pattern layer on side surfaces of the first and second substrates layered to each other, the exterior pattern layer being connected to the interior pattern layer.

10. An electronic apparatus comprising:
a body; and
a component-embedded board in the body,
the component-embedded board comprising:
a substrate comprising a component mounting surface,
a built-in component on the component mounting surface and under an insulating layer,
an interior pattern layer on a side of the built-in component opposite to the substrate configured to radiate heat from the built-in component, and
an exterior pattern layer connected to the interior pattern layer.
